(19) United States
(12) Patent Application Publication
(10) Pub. No.: US 2021/0216144 A1
(43) Pub. Date: Jul. 15, 2021

(54) Method for Generating a Haptic Signal

(71) Applicant: TDK Electronics AG, Munich (DE)

(72) Inventors: Markus Hopfer, Schwanberg (AT); Harald Kastl, Bad Gams (AT); Daniel Neuwirth, Vilshofen (DE); Roman Puchleitner, St. Stefan (AT)

(21) Appl. No.: 17/255,357

(22) PCT Filed: Jan. 28, 2019
(86) PCT No.: PCT/EP2019/051998

§ 371 Date: Dec. 22, 2020

(30) Foreign Application Priority Data
Jul. 12, 2018 (DE) 10 2018 116 912.4
Oct. 24, 2018 (DE) 10 2018 126 473.9

(51) Int. Cl. G06F 3/01; G06F 3/038

(52) U.S. Cl. CPC G06F 3/016; G06F 3/038

(57) ABSTRACT

In an embodiment an arrangement includes an operator control element and a component comprising a piezoelectric actuator, wherein the component is arranged below the operator control element, and wherein the component is configured to generate a haptic signal and generate a vibration on the operator control element.

This patent application is a national phase filing under section 371 of PCT/EP2019/051998, filed Jan. 28, 2019, which claims the priority of German patent application 102018126473.9, filed Oct. 24, 2018, which claims the priority of German patent application 102018116912.4, filed Jul. 12, 2018 each of which is incorporated herein by reference in its entirety.

### TECHNICAL FIELD

The present invention relates to an arrangement having an operator control element and a component for generating a haptic signal, and to an arrangement having a plurality of components for generating a haptic signal. The invention further relates to a medical device, a machine for industrial use, a kitchen appliance, an electronic vaporization device, an electronic device and a stylus which each have an arrangement of this kind.

### BACKGROUND

Mechanical operator control elements of electronic devices, for example mobile telephones, tablets, laptops or input pens, so-called styluses, are increasingly being equipped with touch-sensitive, haptic feedback for better operator control. In this case, the haptic feedback can be generated by way of an operator control element being shifted or lifted. Here, shifts in the region of a few micrometers and deflection times of a few milliseconds are desired in order to stimulate mainly the so-called Pacinian corpuscle and also other pressure receptors of a user.

### SUMMARY

Embodiments provide an improved arrangement having a component which can generate a haptic signal with a low space requirement. Further embodiments provide an improved arrangement having a plurality of components for generating a haptic signal.

Embodiments provide an arrangement which has an operator control element and a component for generating a haptic signal, wherein the component has a piezoelectric actuator and is arranged below the operator control element and is designed to generate a vibration on the operator control element.

Here, any element via which a user of the arrangement or of a device which has the arrangement can make a control command on the arrangement or on other components of the device can be referred to as an operator control element. The operator control element may be, for example, a mechanical element, for example a knob. The operator control element may be any element of a device that is operated by being touched by the user. Said operator control element may be, for example, a push button, a rotary knob, a controller or a pressure-sensitive region of a surface of the electronic device.

The use of a piezoelectric actuator for generating a haptic signal provides significant advantages. A piezoelectric actuator has a short response and decay time. Accordingly, the time point and time period in which the haptic signal is generated can be determined very accurately. Furthermore, the amplitude and the frequency at which the operator control element vibrates can be determined by a variation in the frequency and voltage which are applied to the piezoelectric actuator. As a result, it can be rendered possible to generate different haptic signals on the operator control element.

The component can be arranged, in particular, directly below the operator control element. In this case, the operator control element and the component can bear against one another and touch. In particular, a mechanical reinforcement element of the component can bear against a lower end of the operator control element. In this case, a side of the operator control element that faces away from that side of the operator control element which a user touches when operating the operator control element can be referred to as the lower end.

In comparison to other components for generating vibration, for example unbalance motors or linear resonators, piezoelectric actuators have a small volume. Therefore, a component which has a very low space requirement can be constructed owing to the use of a piezoelectric actuator in the component. Accordingly, the component can meet stringent requirements in respect of miniaturization.

According to one exemplary embodiment, the operator control element and the component for generating a haptic signal can form a unit. Here, a structural unit or a module which can be installed in a device as a whole can be referred to as a “unit”. The operator control element and the component can be designed as a unit particularly in the exemplary embodiments in which the operator control element is a region of a housing. The operator control element and the component can be designed as a unit or module in the other exemplary embodiments too. If the arrangement is used, for example, in a stylus, the operator control element and the component for generating a haptic signal can form a unit.

The piezoelectric actuator can be designed to be deformed as a result of operation of the operator control element and in the process to detect operation of the operator control element. Accordingly, the component for generating the haptic signal can also be used as a sensor which identifies operation of the operator control element. Therefore, the component can have a dual function. Separate components for generating a haptic signal and for identifying operation of the operator control element can be dispensed with in the electronic device.

The operator control element may be a knob. For example, said operator control element may be a so-called home button. The operator control element may also be knobs which are arranged on a lateral housing wall of the device.

As an alternative, the operator control element may also be a region of the housing wall or a region of any other surface of the device which serves as the operator control element. If a region of the housing wall or another surface is used as the operator control element, no openings are required in the housing wall and accordingly seals which usually seal off openings of this kind can be dispensed with. In the case of conventional operator control elements, for example knobs in a housing wall, seals are usually required in order to protect the housing from the ingress of water, dust or dirt. By way of dispensing with the seals, manufacture of the electronic device can be simplified and the costs of the electronic device can be reduced.

The housing wall can have a greater degree of mechanical deformability in the region which serves as the operator control element than in other regions. This can ensure that a vibration remains restricted to that region of the housing wall which serves as the operator control element. It is desirable for only the operator control element and not the entire electronic device to vibrate in order to provide the user with a pleasant user experience.

The housing wall can be thinner in the region which serves as the operator control element than in another region. As an alternative or in addition, that region of the housing wall which serves as the operator control element can be separated from the other regions of the housing wall by at least one notch. The notch and the thinner configuration can each allow vibrations to be locally restricted to that region of the housing wall which serves as the operator control element.

A symbol can be arranged on that region of the housing wall which forms the operator control element. The symbol can indicate an operator control function. The operator control function can be triggered by pressing on the region. For example, the operator control function may be increasing or reducing a volume level.

The component for generating a haptic signal can be clamped in between the operator control element and a rear wall. In this case, the operator control element may be, in particular, the region of the housing wall. The rear wall can be formed by an internal region of the housing wall. The operator control element can be a continuous operator control surface.

A stiffness of the rear wall can be greater than a stiffness of the piezoelectric actuator. Accordingly, the rear wall is not caused to vibrate or caused to vibrate at least only to an insignificant extent when the piezoelectric actuator vibrates. As an alternative or in addition, a stiffness of the piezoelectric actuator can be greater than a stiffness of the operator control element. Accordingly, a vibration of the piezoelectric actuator can be transmitted to the operator control element. The stiffness of the operator control element and the rear wall are determined, inter alia, by the respective thickness. The operator control element can have a lower thickness than the rear wall. This can cause the stiffness of the operator control element to be lower than the stiffness of the rear wall. The stiffness of the operator control element can be 1% to 50% of the stiffness of the piezoelectric actuator.

The stiffness is a mechanical engineering variable. It describes the resistance of a body to elastic deformation due to a force or a moment. The stiffness discussed here may be, in particular, a flexural stiffness of the corresponding elements.

Since the operator control element has a lower stiffness than the piezoelectric actuator and the rear wall, it is possible to ensure that only or at least virtually only the operator control element is deformed when the piezoelectric actuator is caused to vibrate. A strength of the haptic signal can be maximized in this way. A spring action of the operator control element can be optimized by way of suitable selection of the thickness of the operator control element and the connection between the operator control element and the rear wall.

The operator control element and the rear wall can be fixedly connected to one another. For example, the operator control element and the rear wall can be screwed to one another. As an alternative, the operator control element and the rear wall can be in one piece and be formed, for example, from various regions of a single housing wall. In this case, the operator control element can be formed by an outwardly facing region of the housing wall, and the rear wall can be formed by a region of the housing wall that faces into the housing interior. The housing wall can have a cavity which separates the region that forms the operator control element and the region that forms the rear wall. The component for generating the haptic signal can be arranged in the cavity.

The component for generating a haptic signal can be fastened to the operator control element and/or to the rear wall. In particular, the component can be fastened to the operator control element and/or the rear wall by an adhesive bond. The component can be prevented from slipping during operation by way of the component being fastened to at least one of either the operator control element or the rear wall.

The component can have a mechanical reinforcement element which is fastened to the piezoelectric actuator in such a way that a region of the mechanical reinforcement element is moved in a direction which is perpendicular to the longitudinal direction owing to a change in length of the actuator in its longitudinal direction. In this case, the actuator can be arranged in such a way that its longitudinal direction is parallel to the housing wall. The longitudinal direction can be perpendicular to an operating direction of the operating element. The longitudinal direction can be perpendicular to a stacking direction. Therefore, the change in length of the piezoelectric actuator, which change in length is caused by the d31 effect, can be converted into a stroke movement which is perpendicular to the change in length by the mechanical reinforcement element. In this case, the stroke movement can have a substantially greater amplitude than the change in length. For example, the amplitude of the stroke movement can be 5 to 40 times the amplitude of the change in length. In particular, the amplitude of the stroke movement can be 10 to 20 times the amplitude of the change in length. Therefore, considerably stronger vibrations of the operator control element can be caused by the combination of the actuator with the reinforcement element.

The reinforcement element can be a metal bracket. The metal may be, for example, titanium. Titanium has the advantage that its coefficient of thermal expansion is very similar to the coefficient of thermal expansion of the piezoelectric actuator, so that changes in temperature do not result in mechanical stresses.

The mechanical reinforcement element can be free of indentations and have a constant wall thickness. Simple production of the reinforcement element can be rendered possible owing to indentations in the reinforcement element being dispensed with. The mechanical reinforcement element should be free of indentations in particular when the thickness of the mechanical reinforcement element is low enough to not unduly prevent deformation of the reinforcement element. In alternative embodiments, the reinforcement element can have at least one indentation which reduces mechanical resistance to deformation of the mechanical reinforcement element. Particularly in the case of reinforcement elements with a thickness in the case of which deformations of the reinforcement element require a great deal of force, the use of indentations in the reinforcement element may be expedient since the indentations can facilitate deformation of the reinforcement element.

The mechanical reinforcement element can be fastened to the piezoelectric actuator by an adhesive bond.

The electronic device can have a plurality of components for generating a haptic signal, which components each have a piezoelectric actuator and which components are arranged next to one another in the form of an array. In this case, the array can consist of a single row of components. As an alternative, the array can consist of components which are arranged to form an m×n matrix with m columns and n rows, wherein m and n can be any natural numbers. The plurality of components can be arranged below the operator control element and, in particular, bear directly against the operator control element.

Various advantages can be achieved by way of combining a plurality of components for generating a haptic signal. As a result, it is possible to generate a more intense haptic signal since the vibrations of a plurality of components can be used. If the component is additionally used as a sensor for detecting operation of an operator control element, it is also possible to determine, in addition to the fact that the operator control element has been operated, the position of the operator control element at which operation takes place owing to the use of the array of a plurality of components.

Each of the piezoelectric actuators can be read out and driven separately from the other actuators. As a result, each actuator can be used separately as a sensor and for generating haptic feedback.

The array of components can be designed to identify a gesture control operation of the operator control element. The electronic device can further have an evaluation unit which is designed to read out the generated electrical voltage from each of the piezoelectric actuators, to draw a conclusion about the pressure profile which is applied to the respective actuator from the voltage which is generated on the actuators and to convert the pressure profiles into gestures of the gesture control operation. Accordingly, it is possible to use a component which serves for generating a haptic signal to identify control gestures too.

According to a further aspect, embodiments relate to an arrangement which has a plurality of components for generating a haptic signal, which components each have a piezoelectric actuator, wherein the components are arranged next to one another to form an array. The arrangement can further have an evaluation unit which is designed to read out the generated electrical voltage from each of the piezoelectric actuators and to draw a conclusion about the pressure profile which is applied to the respective actuator from the voltage which is generated on the actuators. The plurality of components may be the components which are described in conjunction with the first aspect. In particular, the components can have the mechanical reinforcement elements which are described in conjunction with the first aspect.

Each of the piezoelectric actuators can be read out and driven separately from the other actuators. The evaluation unit can be designed to convert the pressure profiles into gestures of a gesture control operation.

According to a further aspect, embodiments relate to a medical device which has one of the arrangements described above. In this case, the medical device may be an ultrasonic device. As an alternative, the medical device may be an operating table. In this case, the operator control element can be an element which is arranged on the operating table, for example a knob, or a touch-sensitive region of the operating table.

According to a further aspect, embodiments relate to a machine for industrial use which has one of the arrangements described above. The machine for industrial use may be, for example, a CNC mill. The component for generating a haptic signal can cause an operator control element of the CNC mill to vibrate in order to generate the haptic signal.

According to a further aspect, embodiments relate to a kitchen appliance which has one of the arrangements described above. The kitchen appliance may be, for example, a stove or a mixer. In this case, the operator control element can be an element which is arranged on the stove, for example a knob, or a touch-sensitive region of a cooktop plate.

According to a further aspect, embodiments relate to an electronic vaporization device which has one of the arrangements described above. The electronic vaporization device may be, for example, an E-cigarette.

According to a further aspect, embodiments relate to an electronic device which has one of the arrangements described above. The electronic device may be, for example, a mobile telephone, a tablet, a laptop, a smartwatch, a fitness tracker, a heart rate tracker, a sleep tracker or health tracker.

According to a further aspect, embodiments relate to a stylus which has one of the arrangements described above. An input pen for an electronic device can be referred to as a stylus. A stylus is also referred to as a touch pen. A stylus is a pen which can be used for operator control of touchscreens and tablets.

The component for generating the haptic signal can cause a sensing tip of the stylus to vibrate in order to generate the haptic signal. As an alternative or in addition, the component for generating the haptic signal can cause a region of a housing of the stylus to vibrate in order to generate the haptic signal. In this case, the sensing tip can remain motionless.

### BRIEF DESCRIPTION OF THE DRAWINGS

Preferred exemplary embodiments of the present invention will be explained in more detail below with reference to the figures.

FIG. 1 shows a perspective view of a component for generating a haptic signal;

FIG. 2 shows a side view of the component;

FIG. 3 shows a plan view of the top side of the component;

FIG. 4 schematically shows a part of an electronic device;

FIG. 5 shows a schematic view of a part of a further electronic device;

FIG. 6 and FIG. 7 each show an electronic device according to further embodiments;

FIG. 8 shows a stylus;

FIG. 9 shows a stylus according to a further exemplary embodiment; and

FIG. 10 shows a further exemplary embodiment.

### DETAILED DESCRIPTION OF ILLUSTRATIVE EMBODIMENTS

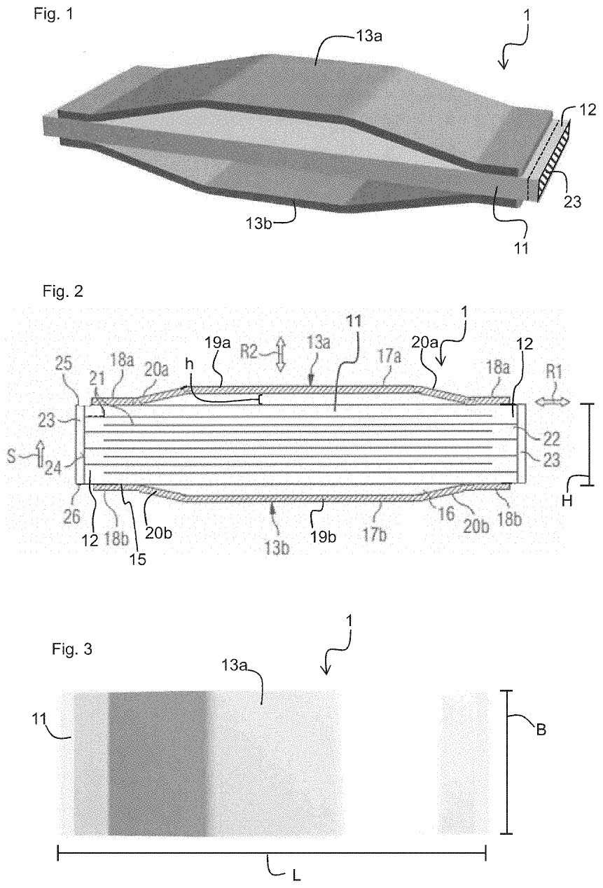

FIG. 1 shows a perspective view of a component 1 for generating a haptic signal. FIG. 2 shows a side view of the component 1. FIG. 3 shows a plan view of the top side of the component 1.

The component 1 has a piezoelectric actuator 11 and two mechanical reinforcement elements 13a, 13b. The component 1 can be used, in particular, in an electronic device for detecting operator control signals and for generating a haptic signal. As an alternative, the component can also be used in other devices, for example in a medical device, a machine for industrial use, a kitchen appliance, an electronic vaporization device or a stylus for detecting operator control signals and for generating a haptic signal.

The piezoelectric actuator 11 has a stack of internal electrodes 21 and piezoelectric layers 22 which are alternately stacked one above the other in a stacking direction S. The piezoelectric actuator 11 has a first external electrode 23, which is arranged on a first end face 24, and a second external electrode 23, which is arranged on a second end face. The internal electrodes 21 are alternately contact-connected to the first external electrode 23 or to the second external electrode 23 in stacking direction S.

The piezoelectric layers 22 may be lead zirconate titanate ceramics (PZT ceramics). The PZT ceramic can further additionally contain Nd and Ni. As an alternative, the PZT ceramic can further additionally comprise Nd, K and possibly Cu. As an alternative, the piezoelectric layers 22 can comprise a compound containing Pb(ZrₓTi₁₋ₓ)O₃+y Pb(Mn_{1/3}Nb_{1/3})O₃.

The internal electrodes 21 comprise copper or consist of copper.

The piezoelectric actuator 11 is cuboidal. In this case, a surface of which the surface normal points in the stacking direction S is referred to as the base surface. The base surface is rectangular. The relatively long side of the base surface defines the length L of the piezoelectric actuator 11 and the relatively short side of the base surface defines the width B of the piezoelectric actuator 11.

The piezoelectric actuator 11 has a length L of between 5 mm and 20 mm and a width B of between 2 mm and 8 mm. According to a first exemplary embodiment, the piezoelectric actuator 11 has a length L of 12 mm and a width B of 4 mm. In a second exemplary embodiment, the piezoelectric actuator 11 has a length L of 9 mm and a width B of 3.75 mm.

The extent of the piezoelectric actuator in stacking direction S defines the height H of the piezoelectric actuator 11. The height H of the piezoelectric actuator 11 can lie between 200 μm and 1000 μm. For example, in the first and the second exemplary embodiment, the height H is 500 μm in each case.

The actuator 11 has two insulation regions 12. The respective insulation region 12 is formed in an end region of the actuator 11. In particular, the respective insulation region 12 is formed in the region of an end face 24 of the actuator.

In the insulation region 12, only internal electrodes 21 of one polarity extend as far as the end face 24 of the actuator 11. The insulation region 12 can be used for contacting the actuator 11. For example, the respective insulation region 12 can be provided with the external electrodes 23 for electrical contacting.

The actuator 11 is designed such that deformation of the actuator 11 takes place (expansion in a first direction R1) when an electrical voltage is applied. In particular, the piezoelectric layers 22 are polarized in such a way that application of an electrical voltage between the internal electrodes 21 leads to transverse contraction of the actuator 11 in the event of which the length L of the actuator 11 changes perpendicularly to the stacking direction S. Consequently, the actuator expands transversely to the polarization direction and to the electric field (d31 effect).

In order to further amplify the effect of the change in length in stacking direction S, the apparatus has two reinforcement elements 13a, 13b. If a voltage is applied to the actuator 11, the reinforcement elements 13a, 13b deform at least partially as a result of the change in the expansion of the actuator 11, as will be described in detail later. In particular, the two reinforcement elements 13a, 13b are dimensioned and connected to the actuator 11 in such a way that in each case one subregion 17a, 17b of the reinforcement elements 13a, 13b executes a stroke movement in the stacking direction S as a result of a change in the length L of the actuator, wherein the amplitude of the stroke movement is greater than the amplitude of the change in the length L of the actuator.

The actuator 11 is arranged between the reinforcement elements 13a, 13b. The reinforcement elements 13a, 13b rest at least partially on the top side 25 or a bottom side 26 of the actuator 11.

The respective reinforcement element 13a, 13b is formed in one piece. The respective reinforcement element 13a, 13b has a rectangular shape. The respective reinforcement element 13a, 13b is of strip-like design. The respective reinforcement element 13a, 13b is curved or bent. The respective reinforcement element 13a, 13b is bow-shaped. For example, the respective reinforcement element has a sheet-metal strip. The respective reinforcement element comprises titanium or consists of titanium. The sheet-metal strip is bent, as will be explained in detail below.

Each of the one-piece reinforcement elements 13a, 13b is subdivided into a plurality of regions or sections. Therefore, the respective reinforcement element 13a, 13b has a subregion or first region 17a, 17b. The subregion 17a, 17b has a first section or central region 19a, 19b in each case.

The subregion 17a, 17b further has two second sections or connection regions 20a, 20b in each case. The two connection regions 20a, 20b of the respective reinforcement element 13a, 13b directly adjoin the central region 19a, 19b of the respective reinforcement element 13a, 13b. In other words, the central region 19a, 19b of the respective reinforcement element 13a, 13b is surrounded by the two connection regions 20a, 20b on either side.

The respective reinforcement element 13a, 13b further has two end regions 18a, 18b. The end regions 18a, 18b directly adjoin the connection regions 20a, 20b of the respective reinforcement element 13a, 13b. In other words, in each case one connection region 20a, 20b connects an end region 18a, 18b to the central region 19a, 19b of a reinforcement element 13a, 13b.

The two end regions 18a, 18b of the respective reinforcement element rest directly on a surface of the actuator 11. Therefore, the first and the second end region 18a of the first reinforcement element 13a rest on a subregion of the top side 25 of the actuator 11. Furthermore, the first and the second end region 18b of the second reinforcement element 13b rest on a subregion of the top side 25 or the bottom side 26 of the actuator 11.

The end regions 18a, 18b are preferably non-releasably connected to the surface of the actuator 11. In particular, the end regions 18a, 18b are connected to the surface of the actuator 11 by an adhesive bond 15.

The respective subregion 17a, 17b is at a distance from the surface of the actuator 11. In particular, a clearance 16 is located between the respective subregion 17a, 17b and the bottom side 26 or the top side 25 of the actuator 11. The clearance 16 has a height h. A free height h between the actuator 11 and the subregion 17a, 17b lies between 0.2 mm and 2.0 and is 0.75 mm in the first exemplary embodiment and 0.4 mm in the second exemplary embodiment, wherein the free height h specifies the maximum distance between the subregion 17a, 17b and the piezoelectric actuator 11 when no voltage is applied to the actuator 11 and no external force acts on the reinforcement element 13a, 13b.

The height h of the clearance 16 varies along the respective subregion 17a, 17b. Therefore, the central region 19a, 19b of the respective subregion 17a, 17b is designed such that it runs parallel to the surface of the actuator 11. Therefore, the height h of the clearance 16 is at a maximum in the region of the central region 19a, 19b. On the contrary, the respective connection region 20a, 20b runs obliquely to the surface of the actuator 11. In other words, the respective connection region 20a, 20b forms an angle with the top side 25 or the bottom side 26 of the actuator 11. The angle is preferably less than or equal to 45°. Therefore, the height h of the clearance 16 decreases in the direction from the central region 19a, 19b toward the end region 18a, 18b of the respective reinforcement element 13a, 13b. Therefore, the respective reinforcement element 13a, 13b has a bent shape.

In alternative embodiments, not shown here, the respective reinforcement element 13a, 13b can have at least one thinned portion, preferably a plurality of thinned portions, between the respective regions of the reinforcement element.

The mechanical reinforcement elements 13a, 13b may each be a titanium sheet which has a thickness of between 0.1 mm and 0.4 mm. For example, the metal sheet can have a thickness of 0.2 mm. Given metal sheet thicknesses in the range mentioned here, deformation of the metal sheet, which deformation is required for executing a stroke movement, can be induced with a low force. Therefore, it is possible to dispense with increasing the deformability of the metal sheet by way of thinned portions. Accordingly, the metal sheet can be free of thinned portions or indentations.

The flat central region 19a, 19b of the respective reinforcement element 13a, 13b can have a length of between 1.5 mm and 5.0 mm. In the first exemplary embodiment, the central region 19a, 19b is 3.5 mm long. In the second exemplary embodiment 19a, 19b, the central region is 2.5 mm long. The end regions 18a, 18b can have a length of between 1.0 mm and 0.5 mm. In the first and in the second exemplary embodiment, the end regions 18a, 18b are each 0.7 mm long. A shorter length than 0.5 mm should not be selected since otherwise the adhesive bond 15 between the end regions 18a, 18b and the actuator 11 possibly may not be of sufficiently thick design.

An overall height of the component consisting of the actuator 11 and the two reinforcement elements 13a, 13b can lie between 5.0 mm and 1.0 mm. In the first exemplary embodiment, the overall height is 2.4 mm. In the second exemplary embodiment, the overall height is 1.7 mm.

Miniaturization is an important consideration for use of the component in electronic devices and also in other devices. Components which generate a haptic signal and in the process have only a very low space requirement are provided owing to the use of the components, described here, having the specified dimensions. A component having the dimensions specified above can be positioned, for example, below a knob on the side wall of a mobile telephone or a clock casing.

In the first exemplary embodiment, an applied voltage of 60 V produces a free deflection, or a stroke, of 25 μm and a blocking force of 3.5 N. In this case, the stiffness is 0.14 N/μm. In the second exemplary embodiment, an applied voltage of 60 V produces a free deflection, or a stroke, of 15 μm and a blocking force of 2.5 N. In this case, the stiffness is 0.16 N/μm.

If voltage is now applied to the actuator 11, the subregions 17a, 17b of the respective reinforcement element 13a, 13b move relative to the actuator 11 in a second direction R2. The second direction R2 is perpendicular to the first direction R1. The second direction R2 runs along the stacking direction S.

In particular, the central regions 19a, 19b move in the second direction R2. In this case, the respective reinforcement element 13a, 13b bends at transitions between the central region 19a, 19b and connection regions 20a, 20b and also between connection regions 20a, 20b and end regions 18a, 18b.

On the contrary, a movement of the end regions 18a, 18b in the second direction R2 is prevented by the adhesive bond 15 to the actuator 11. Instead, the end regions 18a, 18b move in the first direction R1 with the actuator 11. Therefore, a relative movement takes place between the end regions 18a, 18b and the subregions 17a, 17b.

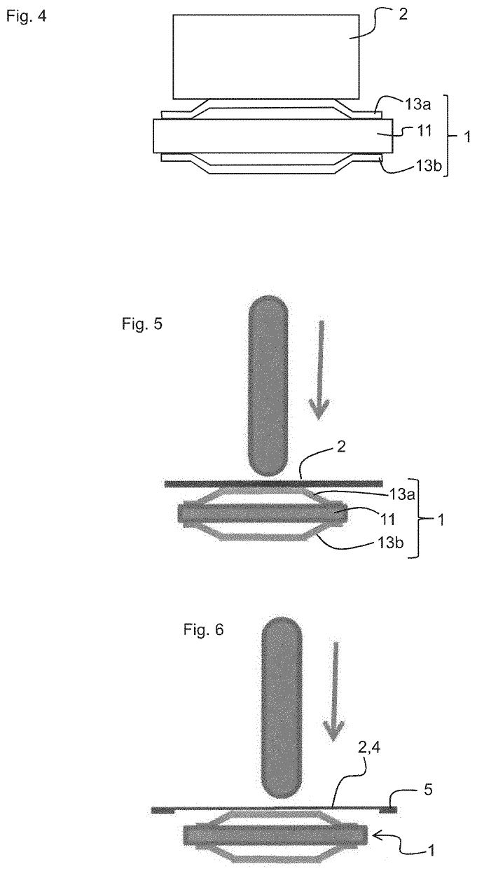

FIG. 4 schematically shows an arrangement in which a component 1 for generating a haptic signal, which component has the piezoelectric actuator 11 and the reinforcement elements 13a, 13b, is arranged below an operator control element 2.

The arrangement can be used, for example, in an electronic device which has a housing wall 3. The operator control element 2 is arranged in the housing wall 3. The operator control element 2 may be a knob. The operator control element 2 can be operated by a user of the electronic device by pressing. The component 1 having the piezoelectric actuator 11 and the two reinforcement elements 13a, 13b is arranged directly below the operator control element 2. In this case, the reinforcement element 13a, which is arranged on the top side 25 of the piezoelectric actuator 11, bears directly against the operator control element 2.

If the operator control element 2 is pressed, the operator control element 2 exerts a force on the reinforcement element 13a. Owing to the force which is exerted on the reinforcement element 13a, said reinforcement element is deformed, wherein, in particular, the end regions 18a, 18b are moved away from one another in the first direction R1. The reinforcement element 13a is fastened to the piezoelectric actuator 11 in such a way that the piezoelectric actuator 11 is also deformed in the longitudinal direction owing to the force which is exerted on the reinforcement element 13a and the associated deformation of the reinforcement element 13a. As a result, a voltage is generated in the piezoelectric actuator 11. This voltage can be detected and in this way it can be concluded that the operator control element 2 has been operated. To this end, the piezoelectric actuator 11 can be connected to a microcontroller which evaluates the voltages which are generated on the piezoelectric actuator 11. The piezoelectric actuator 11 can therefore be used in the electrical device as a sensor which identifies operation of the operator control element 2.

Furthermore, the piezoelectric actuator 11 can also be used for generating a haptic signal. If an electrical voltage is applied to the actuator 11, the actuator 11 deforms in the longitudinal direction and the reinforcement element 13a accordingly executes a stroke movement. On account of the arrangement of the component 1 directly below the operator control element 2, the operator control element 2 likewise executes the stroke movement when the reinforcement element 13a executes the stroke movement. As a result, a vibration of the operator control element 2 can be generated, and this vibration can be perceived by the user as a haptic signal on the operator control element 2. For example, this haptic signal can be used as haptic feedback which confirms to the user that the operator control element 2 has been operated.

FIG. 5 shows a schematic view of a part of a further device. In the exemplary embodiment shown in FIG. 5, the component 1 having the piezoelectric actuator 11 and the reinforcement elements 13a, 13b is arranged below an operator control element 2 of the electronic device. The operator control element 2 is a region 4 of the housing wall.

The arrangement of the piezoelectric actuator below the housing wall renders it possible to use the housing wall itself as the operator control element. If the housing wall is pressed by a finger or a pen as indicated in FIG. 5, the housing wall deforms. As a result, the actuator which is arranged directly below the housing wall is likewise deformed and operation of the housing wall can be identified in an analogous manner to the exemplary embodiment described in FIG. 4.

The piezoelectric actuator 11 can further be used to make that region 4 of the housing wall 3 which is used as the operator control element 2 to vibrate and in this way to generate a haptic signal.

If the housing wall 3 itself is used as the operator control element 2, this has the advantage that seals which are otherwise often required in order to construct an operator control element 2, which is arranged in the housing wall 3, in such a way that the housing interior is protected against dust, dirt and water can be dispensed with.

A conventional operator control element 2, such as a button of the knob shown in FIG. 4 for example, generally has a low mass of a few grams. The operator control element 2 and the component 1 together form, in simplified form, a spring-mass system. The resonant frequency f₀ (=characteristic frequency/free oscillation of the spring-mass system given single excitation) results in:

$${f}_{0} = \frac{1}{2 π} \sqrt{\frac{D}{m}} ,$$

where D is the stiffness and m is the mass of the system.

If operator control, as mentioned above, takes place directly via the housing wall 3, the entire system comprising the component 1 and the housing has to be taken into consideration. In this case, the description is more complicated since the resonant frequency depends to a great extent on the integration of the component 1 into the housing. Here, it is necessary to ensure that the entire housing does not vibrate, but rather as far as possible only the region 3 of the housing wall above the component 1.

FIG. 6 shows a device according to a further embodiment. In comparison to the embodiment shown in FIG. 5, the housing wall 3 would be manufactured with a lower wall thickness in the region 4, which is used as the operator control element 2, than in the regions 5 which are not used as the operator control element 2. Better transmission of pressure from the housing wall 3 to the actuator 11 can be rendered possible owing to the smaller wall thickness of the housing wall 3 in the region 4 which serves as the operator control element 2. On account of its reduced thickness, the region 4 of the housing wall 3 also has a greater degree of mechanical deformability than in the device shown in FIG. 5. Therefore, the region 4 can be caused to vibrate more intensely by the actuator 11, so that a stronger haptic signal is generated. Furthermore, the different thickness of the regions 4, 5 of the housing wall 3 can ensure that those regions 5 of the housing wall 3 which do not serve as the operator control element 2 are not caused to vibrate, but rather the vibration remains locally limited. The relatively thin configuration of the region 4 therefore renders it possible for the region 4 to be insulated from the other regions 5 of the housing wall in respect of vibration.

As an alternative or in addition, that region 4 of the housing wall 3 which serves as the operator control element 2 can be separated from the other regions 5 of the housing wall 3 by one or more notches. Local limiting of the vibration can also be induced in this way.

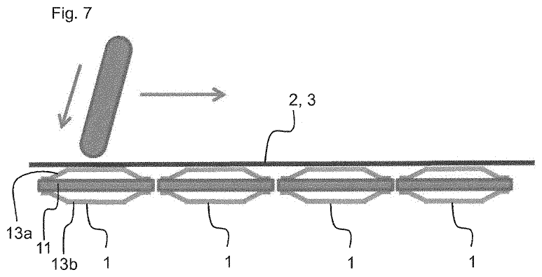

FIG. 7 shows an arrangement according to a further embodiment. A region 4 of the housing wall 3 is used as the operator control element 2 in this embodiment too. A plurality of components 1 for generating a haptic signal, which plurality of components are arranged to form an array, are arranged below the region of the housing wall.

The mechanical reinforcement elements 13a, which are arranged on the top side 25 of the respective actuator 11, bear against an inner side of the housing wall 3 in this case. Each of the piezoelectric actuators 11 in the array can be driven separately and read out separately. As a result, it can be rendered possible not only to identify operation of the operator control element 2 but rather also to identify the position at which the operator control element 2 is operated. As a result, identification of a gesture control operation can be rendered possible. For example, it is possible to identify when a finger or a pen is swiped across the operator control element 2. In particular, the direction of the operator control operation and the speed of the operator control operation can be identified in this case.

If the user now operates the device by means of gesture control, for example by way of the user moving a finger or a pen over that region 4 of the housing wall 3 which is provided as the operator control element 2 above the actuators 11, a different pressure profile and therefore a different electrical voltage are applied to each actuator 11 depending on the respective pressing force and the movement speed. These signals can be converted into the corresponding gestures by a microcontroller which is connected to the actuators 11.

For example, the actuators n can be installed below the lateral housing wall 3 of an electronic device and replace the volume button. Swiping in one direction can be equivalent to the function “louder” and swiping in the opposite direction can be equivalent to the function “quieter”.

The use of the array of piezoelectric actuators 1 furthermore renders it possible for a haptic signal to be generated locally on the operator control element 2 at different positions. Owing to the plurality of piezoelectric actuators n, a haptic signal with a different intensity can be generated depending on how many of the actuators n are used for generating the haptic signal. As a result, it can be rendered possible, for example, to adjust the intensity of the haptic signal in such a way that it provides the user with information relating to a volume level, for example the intensity of the haptic signal can be proportional to a music volume level.

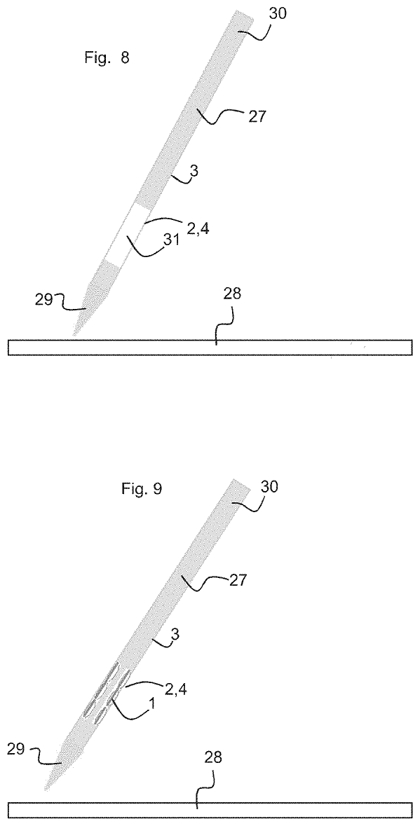

FIG. 8 shows a stylus 27 which has the arrangement described above. The stylus 27 is a pen-like input and/or output device. The stylus 27 can be used, in particular, as a pen-like input and/or output device for an operator control surface 28. The operator control surface 28 may be, for example, a screen of a mobile telephone or of a tablet. The operator control surface 28 may also be a touch-sensitive area of a kitchen appliance, for example a cooktop, or of a medical device, for example an operating table. The operator control surface 28 may also be a plate, for example a tabletop or a glass plate. In this case, the plate can be used as part of an augmented-reality application. Furthermore, the operator control surface 28 may also be a virtual area.

The stylus 27 has the arrangement described above which renders it possible to send a haptic signal to the user. In order to generate the haptic signal, either a sensing tip 29 or a region of a main body 30 of the stylus 27 is caused to vibrate. As a result, the user can be provided with a haptic impression. For example, the user can be provided with the impression that the stylus 27 has been moved over a surface. To this end, the stylus 27 has the arrangement described above with at least one component 1 for generating a haptic signal, which component is designed to generate vibrations by way of which the user is given the haptic impression of movement of the stylus 27 over the surface.

The stylus 27 can be used in two different operating modes. The first operating mode is also referred to as a “playback mode”. In this case, the piezoelectric actuator 11 is used for generating a vibration which gives a user a haptic impression. The second operating mode is also referred to as a “scanning mode”. In this case, the stylus 27 is guided along a surface. The force which is exerted on the stylus 27 by the surface in this case is identified by the stylus 27, in particular by the piezoelectric actuator 11 or an associated electronics system, and a surface profile which is calculated from said force is stored. A haptic signal which plays back, for example, the surface profile which was stored in the “scanning mode” can be generated in the “playback mode”.

The stylus 27 shown in FIG. 8 has a unit 31 having a component 1 for generating a haptic signal, which component has a piezoelectric actuator 11, and an operator control element 2. The component 1 is not depicted in FIG. 8 for improved clarity. The operator control element 2 is a region 4 of a housing wall 3 of the stylus 27. If a haptic signal is intended to be generated, the piezoelectric actuator 11 can cause a region 4 of the housing wall 3 to vibrate to this end.

The stylus 27 further has the sensing tip 29. The sensing tip 29 is arranged at a writing end of the stylus 27, which writing end faces the operator control surface 28 when the stylus 27 is in use. The sensing tip 29 can form a sampling unit. A proximity sensor and/or other electronic components can be arranged in the sensing tip 29.

The stylus 27 further has the main body 30. The arrangement is accommodated in the main body 30. A drive electronics system, a power supply and various sensors can further be arranged in the main body 30. In this case, the sensors can comprise, for example, an acceleration sensor and/or a travel sensor and/or a proximity sensor. The drive electronics system can be designed to drive the piezoelectric actuator 11. In this case, a signal which is applied to the piezoelectric actuator 11 by the drive electronics system can be adjusted taking into account measurement data which is acquired by the sensors.

FIG. 9 shows the stylus 27 according to a second exemplary embodiment. In the second exemplary embodiment, the stylus 27 has a plurality of components 1 for generating a haptic signal. The components 1 are each arranged in the main body 30 of the stylus 27. The components 1 are arranged close to the housing wall 3 of the stylus 27. The further features of the stylus 27 according to the second exemplary embodiment correspond to the stylus 27 shown in FIG. 8.

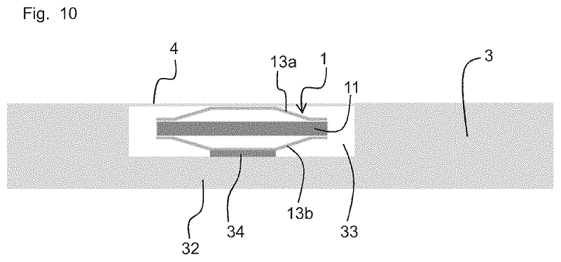

FIG. 10 shows a further exemplary embodiment.

The component 1 for generating the haptic signal is clamped in between an operator control element 2 and a rear wall 32. In this case, the operator control element 2 is formed by a region 4 of a housing wall 3. The rear wall 32 is formed by a further region of the housing wall 3. The rear wall 32 and the operator control element 2 can also be formed by housing parts which are screwed to one another or fixedly connected to one another in some other way.

A cavity 33 is arranged between the operator control element 2 and the rear wall 32. The component 1 for generating the haptic signal is arranged in the cavity 33. The component 1 has the piezoelectric actuator 11 and two reinforcement elements 13a, 13b. One of the reinforcement elements 13b is adhesively bonded to the rear wall 32 by an adhesive layer 34.

The operator control element 2 is a continuous operator control surface. The operator control surface is visible to and operable by a user. A symbol which indicates a specific operator control function, for example increasing or reducing a volume level, can be arranged on the operator control surface.

The stiffness of the rear wall 32 is typically very much greater than the stiffness of the piezoelectric actuator 11. The stiffness of the actuator 11 is, in turn, greater than that of the operator control element 2 which is formed here by a thin location of the housing, which thin location could also be referred to as a membrane. A typical value for the stiffness of the membrane lies in the range of from 1%-50% of the stiffness of the actuator 11.

The abovementioned design ensures that only the thin location is deformed and therefore the intensity of the haptic feedback to the user is maximized. In addition, a spring action of the thin location can be optimized by varying the thickness or the connection between the thin location and the rear wall 32.

Although the invention has been illustrated and described in detail by means of the preferred embodiment examples, the present invention is not restricted by the disclosed examples and other variations may be derived by the skilled person without exceeding the scope of protection of the invention.

1-30. (canceled)

31. An arrangement comprising:
an operator control element; and
a component comprising a piezoelectric actuator,
wherein the component is arranged below the operator control element, and
wherein the component is configured to:
generate a haptic signal, and
generate a vibration on the operator control element.

32. The arrangement according to claim 31, wherein the operator control element and the component form a unit.

33. The arrangement according to claim 31, wherein the piezoelectric actuator is configured to be deformed as a result of operating the operator control element and as a result of detecting an operation of the operator control element.

34. The arrangement according to claim 31, wherein the operator control element is a knob.

35. The arrangement according to claim 31, wherein the operator control element is a region of a housing wall.

36. The arrangement according to claim 35, wherein the housing wall has a greater degree of mechanical deformability in the region which serves as the operator control element than in other regions.

37. The arrangement according to claim 35,
wherein the housing wall is thinner in the region which serves as the operator control element than in another region, and/or
wherein the region of the housing wall which serves as the operator control element is separated from the other regions of the housing wall by at least one notch.

38. The arrangement according to claim 35, wherein a symbol which indicates an operator control function is arranged on that region of the housing wall which forms the operator control element.

39. The arrangement according to claim 31, wherein the component is clamped in between the operator control element and a rear wall.

40. The arrangement according to claim 39,
wherein a stiffness of the rear wall is greater than a stiffness of the piezoelectric actuator, and/or
wherein a stiffness of the piezoelectric actuator is greater than a stiffness of the operator control element.

41. The arrangement according to claim 39, wherein the operator control element and the rear wall are fixedly connected to one another.

42. The arrangement according to claim 39, wherein the component is fastened to the operator control element and/or to the rear wall.

43. The arrangement according to claim 31, wherein the component has a mechanical reinforcement element fastened to the piezoelectric actuator such that a region of the mechanical reinforcement element is configured to move in a direction perpendicular to a longitudinal direction of the piezoelectric actuator in response to a change in length of the piezoelectric actuator.

44. The arrangement according to claim 43, wherein the mechanical reinforcement element is a metal bracket.

45. The arrangement according to claim 43,
wherein the mechanical reinforcement element is free of indentations and has a constant wall thickness, or
wherein the mechanical reinforcement element has at least one indentation reducing mechanical resistance to deformation of the mechanical reinforcement element.

46. The arrangement according to claim 31, wherein the arrangement comprises a plurality of components each configured to generate a haptic signal, wherein each component has a piezoelectric actuator, and wherein the components are arranged next to one another forming an array.

47. The arrangement according to claim 46, wherein each of the piezoelectric actuators are separately readable and separately drivable from the other piezoelectric actuators.

48. The arrangement according to claim 46, wherein the array of components is configured to identify a gesture control operation of the operator control element.

49. The arrangement according to claim 48, further comprises an evaluation unit configured to:
read out a generated electrical voltage from each of the piezoelectric actuators,
determine a pressure profile applicable to the respective actuator from the generated electrical voltage, and
convert the pressure profiles into gestures of the gesture control operation.

50. A medical device comprising:
the arrangement according to claim 31.

51. A machine for industrial use comprising:
the arrangement according to claim 31.

52. A kitchen appliance comprising:
the arrangement according to claim 31.

53. An electronic vaporization device comprising:
the arrangement according to claim 31.

54. An electronic device comprising:
the arrangement according to claim 31.

55. The electronic device according to claim 54, wherein the electronic device is a mobile telephone, a tablet, a laptop, a smartwatch, a fitness tracker, a heart rate tracker, a sleep tracker or a health tracker.

56. A stylus comprising:
the arrangement according to claim 31.

57. The stylus according to claim 56, wherein the component is configured to cause a sensing tip of the stylus to vibrate, or wherein the component is configured to cause a region of a housing of the stylus to vibrate.

58. An arrangement comprising:
a plurality of components each configured to generate a haptic signal, wherein each component has a piezoelectric actuator, and wherein the components are arranged next to one another forming an array; and
an evaluation unit configured to:
read out a generated electrical voltage from each of the piezoelectric actuators; and
determine a pressure profile applicable to the respective actuator from the generated voltage.

59. The arrangement according to claim 58, wherein each piezoelectric actuator is separately readable and separately driven from the other piezoelectric actuators.

60. The arrangement according to claim 59, wherein the evaluation unit is configured to convert the pressure profiles into gestures of a gesture control operation.

61. A medical device comprising:
the arrangement according to claim 58.

62. A machine for industrial use comprising:
the arrangement according to claim 58.

63. A kitchen appliance comprising:
the arrangement according to claim 58.

64. An electronic vaporization device comprising:
the arrangement according to claim 58.

65. An electronic device comprising:
the arrangement according to claim 58.

66. The electronic device according to claim 65, wherein the electronic device is a mobile telephone, a tablet, a laptop, a smartwatch, a fitness tracker, a heart rate tracker, a sleep tracker or a health tracker.

67. A stylus comprising:
the arrangement according to claim 58.
